(19) United States
(12) Patent Application Publication
(10) Pub. No.: US 2026/0068556 A1
(43) Pub. Date: Mar. 5, 2026

(54) RESPONSIVE LAYER FOR LOW FREQUENCY LINE WIDTH ROUGHNESS REDUCTION

(71) Applicant: Applied Materials, Inc., Santa Clara, CA (US)

(72) Inventors: RUDY WOJTECKI, East Garrison, CA (US); SIVANANDHA KRISHNAN KANAKASABAPATHY, Pleasanton, CA (US); ZHIYU HUANG, Sunnyvale, CA (US)

(21) Appl. No.: 19/287,622

(22) Filed: Jul. 31, 2025

Related U.S. Application Data
(60) Provisional application No. 63/688,864, filed on Aug. 29, 2024.

(51) Int. Cl. H01L 21/02; G03F 7/00; G03F 7/004; H01L 21/311

(52) U.S. Cl. CPC H01L 21/02348; G03F 7/0043; G03F 7/70033

(57) ABSTRACT

Embodiments described herein relate to a method that includes forming a pattern in a resist layer that is provided over a patterning stack that includes a responsive layer. In an embodiment, the method may include transferring the pattern into the responsive layer, and applying a treatment to the responsive layer. In an embodiment, the treatment induces a tensile stress in the responsive layer and reduces a line width roughness (LWR) of the pattern.

### CROSS-REFERENCE TO RELATED APPLICATIONS

This application claims the benefit of U.S. Provisional Application No. 63/688,864, filed on Aug. 29, 2024, the entire contents of which are hereby incorporated by reference herein.

### BACKGROUND

### 1) Field

Embodiments relate to the field of semiconductor manufacturing and, in particular, extreme ultraviolet (EUV) patterning with a responsive underlayer that is capable of being modified by a treatment that induces a tensile stress in the responsive underlayer.

### 2) Description of Related Art

Extreme ultraviolet (EUV) photoresists allow for the continued scaling to smaller features that are patterned on a semiconductor substrate. One limiting factor to the increased scaling is the presence of high line width roughness (LWR). LWR can generally be characterized into two components: high frequency LWR and low frequency LWR. High frequency LWR generally includes roughness measurements of the sidewalls of the patterned photoresist on the scale of approximately 5 nm or less. Low frequency LWR generally includes roughness measurements of the sidewalls of the patterned photoresist on the scale of approximately 100 nm or more.

In order to improve pattern transfer, both high frequency LWR and low frequency LWR should be addressed. High frequency LWR can be reduced through certain etching processes. However, issues related to low frequency LWR cannot be addressed through etching processes.

### SUMMARY

Embodiments described herein relate to a method that includes forming a pattern in a resist layer that is provided over a patterning stack that includes a responsive layer. In an embodiment, the method may include transferring the pattern into the responsive layer, and applying a treatment to the responsive layer. In an embodiment, the treatment induces a tensile stress in the responsive layer and reduces a line width roughness (LWR) of the pattern.

Embodiments described herein relate to a method that includes forming a pattern in an extreme ultraviolet (EUV) compatible resist layer that is provided over a patterning stack that includes a responsive layer that includes silicon. In an embodiment, the method may further comprise transferring the pattern into the responsive layer that has a first low frequency line width roughness (LWR). In an embodiment, the method may further include treating the responsive layer with a treatment that induces a tensile stress in the responsive layer, and the tensile stress modifies the responsive layer to produce a second LWR that is lower than the first LWR.

Embodiments described herein relate to a method that includes forming a pattern in a responsive layer of a patterning stack. In an embodiment, the responsive layer includes silicon. In an embodiment, the process may continue with treating the responsive layer with an ultraviolet (UV) radiation exposure or a thermal oxidation in order to induce a tensile stress in the responsive layer. In an embodiment, the method may further include transferring the pattern into a layer of the patterning stack below the responsive layer.

### BRIEF DESCRIPTION OF THE DRAWINGS

FIG. 1 is a plan view illustration of a patterned resist layer that exhibits low frequency line width roughness (LWR), in accordance with an embodiment.

FIG. 2A is a plan view illustration of a patterning stack with a patterned responsive layer in an as deposited state, in accordance with an embodiment.

FIG. 2B is a plan view illustration of the patterning stack in FIG. 2A after the responsive layer is exposed to a treatment that induces a tensile stress in the patterned responsive layer, in accordance with an embodiment.

FIGS. 3A-3G are cross-sectional illustrations depicting a process for patterning a patterning stack with a responsive underlayer that is treatable to induce a tensile stress that reduces the low frequency LWR, in accordance with an embodiment.

FIGS. 4A-4C are cross-sectional illustrations depicting a process for patterning a patterning stack with a responsive underlayer that is treatable to induce a tensile stress that reduces the low frequency LWR, in accordance with an additional embodiment.

FIG. 5 is a flow diagram depicting a process for patterning a patterning stack with a responsive underlayer that is treatable to induce a tensile stress that reduces the low frequency LWR, in accordance with an embodiment.

FIG. 6 illustrates a block diagram of an exemplary computer system that may be used in conjunction with a processing tool, in accordance with an embodiment.

### DETAILED DESCRIPTION

Embodiments described herein include extreme ultraviolet (EUV) patterning stacks with a responsive underlayer that is capable of being modified by a treatment that induces a tensile stress in the responsive underlayer. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

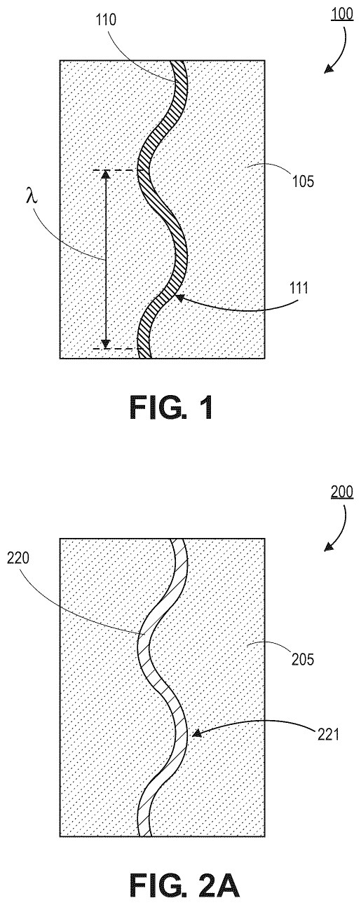

As noted above, both high frequency line width roughness (LWR) and low frequency LWR can contribute to poor pattern transfer through a patterning stack below a photoresist material, such as an EUV photoresist material. While etching processes can be used to address poor high frequency LWR, it is harder to reduce low frequency LWR. An example, of low frequency LWR of a device 100 is shown in FIG. 1. As shown, a patterned resist layer 110 over a substrate 105 may have a long-range undulation as indicated by the curved sidewalls 111 on the patterned resist layer 110. For example, peak-to-peak distances of the curvature (represented by the distance λ) may be greater than approximately 5 nm, up to approximately 50 nm or more, up to approximately 100 nm or more, or up to approximately 500 nm or more. Volumetric changes to the patterned resist layer 110 are necessary in order to reduce the low frequency LWR.

However, it is difficult to design photoresist materials that are capable of volumetric changes post deposition since the photoresist materials may be specifically tuned for optimal chemical conversion in response to exposure to radiation (e.g., ultraviolet (UV) radiation or EUV radiation). Accordingly, embodiments disclosed herein may include the use of a patterning stack that includes a responsive layer that is capable of undergoing a volumetric change in response to a treatment. For example, the responsive layer may be provided below the photoresist layer. After the photoresist layer is patterned, the pattern may be transferred into the responsive layer. The pattern that is transferred into the responsive layer may still have suboptimal low frequency LWR. After the responsive layer is patterned, a treatment may be applied that induces a tensile stress in the responsive layer that drives a strain response. The strain response drives a volumetric change in the responsive layer that straightens the sidewall profile in order to reduce the low frequency LWR. The improved pattern can then be transferred into additional layers of the patterning stack.

In some embodiments, the responsive layer may comprise silicon, such as an amorphous silicon material. The amorphous silicon can be treated with an oxidation process. For example, suitable oxidation processes may include a thermal oxidation process, a plasma oxidation process (e.g., a radical plasma or a direct oxygen plasma, etc.), or the like. The introduction of oxygen into the responsive layer increases the volume of the responsive layer. This produces a tensile stress that results in a strain response that expands the responsive layer in order straighten the sidewall surfaces and reduces low frequency LWR.

In another embodiment, the responsive layer may comprise silicon and nitrogen (e.g., SiN). The silicon nitride may also be deposited in order to have a high hydrogen concentration. For example, the atomic percentage of hydrogen may be approximately 0.5% or higher. The high atomic percentage of hydrogen is used in order to modify the responsive layer in response to the treatment. For example, a low temperature UV exposure may be used in order to remove hydrogen from the responsive layer. Oxygen may also be present in the SiN in some embodiments. The low temperature prevents the responsive layer from undergoing structural relaxation in order to enhance the tensile stress. The tensile stress may induce a strain that modifies the profile of sidewalls in order to reduce the low frequency LWR.

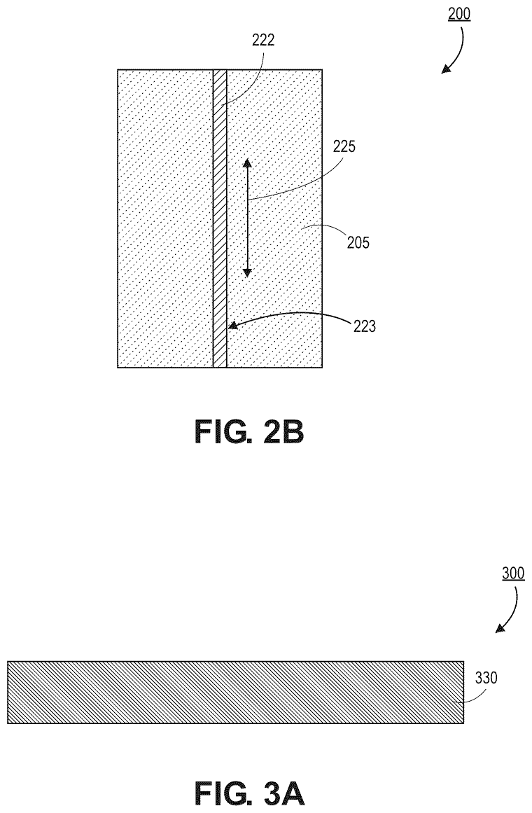

Referring now to FIGS. 2A and 2B, a pair of plan view illustrations of a device 200 with a responsive layer 220 that is treated to reduce low frequency LWR is shown, in accordance with an embodiment. In FIG. 2A, the responsive layer 220 is shown over the substrate 205. The responsive layer 220 may be patterned using an overlying resist layer (not shown) as a mask. The resulting patterned responsive layer 220 may have sidewalls 221 that exhibit unacceptable low frequency LWR as indicated by the curvature of the responsive layer 220.

Referring now to FIG. 2B, a plan view illustration of the device 200 after a treatment is applied to the responsive layer 220 to form a treated responsive layer 222 is shown, in accordance with an embodiment. The treatment may be a UV exposure, an annealing treatment, or a thermal oxidation treatment. The treatment may produce a tensile stress 225 in the treated responsive layer 222 that produces a volumetric change in the treated responsive layer 222. The tensile stress 225 elongates the treated responsive layer 222 and reduces the curvature so that the sidewalls 223 have a more linear profile. As such, the low frequency LWR can be significantly reduced. The treated responsive layer 222 may then be used to transfer a pattern with improved low frequency LWR into the underlying substrate 205.

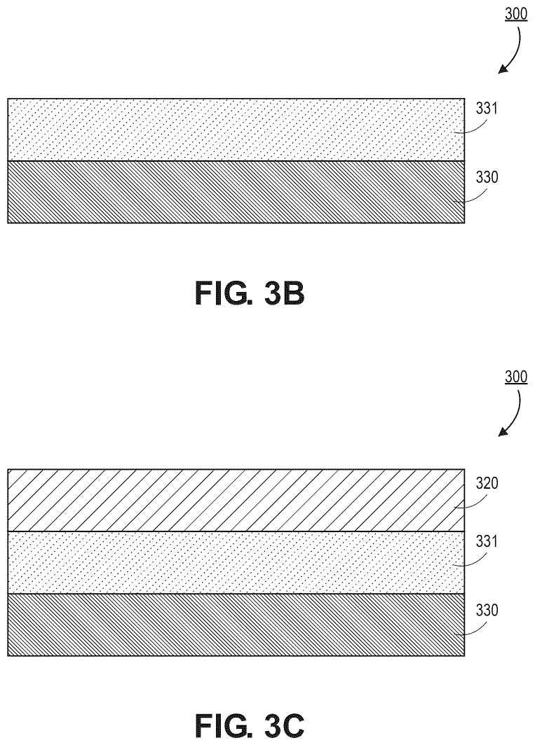

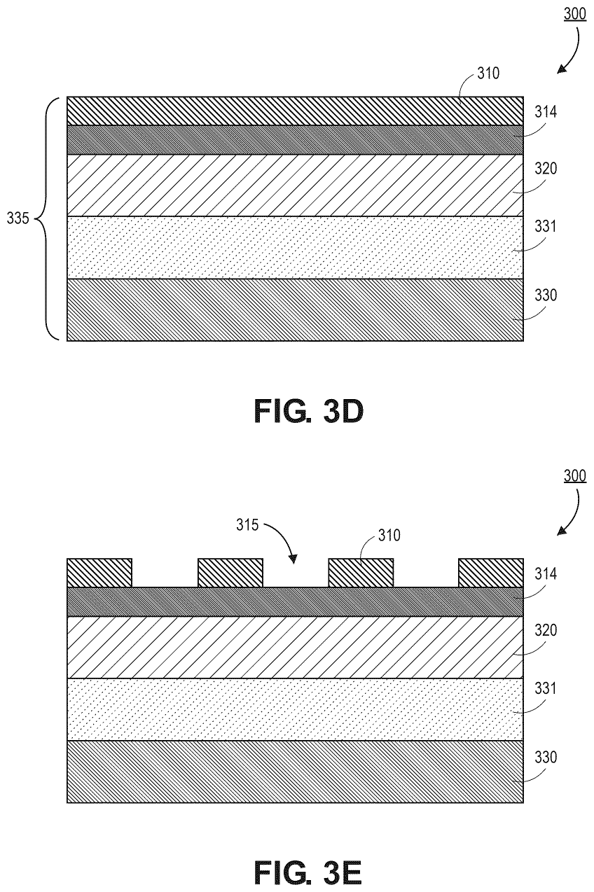

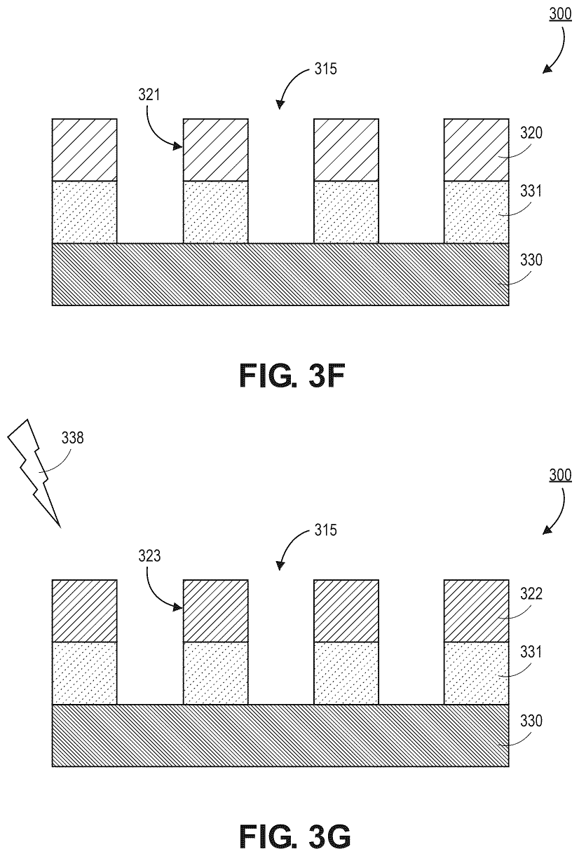

Referring now to FIGS. 3A-3G, a series of cross-sectional illustrations depicting a process for patterning a patterning stack with improved low frequency LWR is shown, in accordance with an embodiment. The patterning stack may include a responsive layer that is treatable in order to generate a tensile stress that drives an improvement in the low frequency LWR. That is, the responsive layer may be deposited in the patterning stack in a first state that is substantially unstressed, and the treatment may be used to induce a tensile stress in the treated responsive layer that reduces the low frequency LWR.

Referring now to FIG. 3A, a cross-sectional illustration of a portion of a device 300 with a first layer 330 of a patterning stack is shown, in accordance with an embodiment. In an embodiment, the first layer 330 may comprise silicon and oxygen, such as a silicon oxide layer. For example, a tetraethyl orthosilicate (TEOS) based silicon oxide may be formed as a layer in the patterning stack. The first layer 330 may be provided over an underlying layer (not shown) that is desired to be patterned, or the first layer 330 may be the desired layer that is to be patterned. An underlying layer may comprise a semiconductor substrate, such as a silicon wafer or any other semiconductor material. Though, other types of substrates may also be patterned with embodiments described in greater detail herein.

Referring now to FIG. 3B, a cross-sectional illustration of the device 300 after a second layer 331 of the patterning stack is formed over the first layer 330 is shown, in accordance with an embodiment. In an embodiment, the second layer 331 may comprise carbon or the like. For example, the second layer 331 may comprise an amorphous carbon layer that is deposited with any suitable process, such as a chemical vapor deposition (CVD) process.

Referring now to FIG. 3C, a cross-sectional illustration of the device 300 after a responsive layer 320 is deposited over the second layer 331 is shown, in accordance with an embodiment. In an embodiment, the responsive layer 320 may be a material that is capable of undergoing a volumetric change, a structural change, a shape change, or the like in response to a treatment. In some embodiments, the responsive layer 320 comprises a material in which a tensile stress can be induced through the application of a treatment. Accordingly, the responsive layer 320 can be formed in a state with a first internal stress (e.g., no internal stress or a low internal stress) and be converted into a state with a second internal stress that is higher than the first internal stress. Particularly, embodiments may include a responsive layer 320 that is capable of exhibiting an increase in a tensile stress in response to a particular treatment.

In one embodiment, the responsive layer 320 may comprise silicon. In a first embodiment, the responsive layer 320 may comprise a silicon-based material composition that has an amorphous structure. In a second embodiment, the responsive layer 320 may comprise a combination of one or more of silicon, nitrogen, hydrogen, and oxygen. For example, the responsive layer 320 may comprise substantially silicon and nitrogen (e.g., SiN) with a relatively high atomic concentration of hydrogen. For example, an atomic concentration of hydrogen may be approximately 0.5% or higher, approximately 1% or higher, or approximately 5% or higher. The atomic concentration of hydrogen may be controlled in order to induce a desired amount of tensile stress in the responsive layer 320 after the treatment, as will be described in greater detail herein. In some embodiments, relatively high atomic percentages of hydrogen may be obtained through low temperature deposition of the SiN responsive layer 320. For example, deposition temperatures below approximately 450° C., below approximately 400° C., or below approximately 300° C. may be used.

In an embodiment, the responsive layer 320 may be deposited with any suitable deposition process. For example, the deposition process may include a CVD process, a plasma enhanced CVD (PECVD) process, a physical vapor deposition (PVD) process, an atomic layer deposition (ALD) process, a plasma enhanced ALD (PEALD) process, or the like.

Referring now to FIG. 3D, a cross-sectional illustration of the device 300 after a resist layer 310 is formed over the responsive layer 320 is shown, in accordance with an embodiment. In an embodiment, the resist layer 310 may be deposited directly over the responsive layer 320. In other embodiments, an underlayer 314 may be provided between the resist layer 310 and the responsive layer 320. The underlayer 314 may be used to improve the chemical conversion of the resist layer 310 during exposure (e.g., UV exposure or EUV exposure). The underlayer 314 may also provide improved adhesion to the responsive layer 320. In an embodiment, the resulting stack of layers (e.g., one or more of the first layer 330, the second layer 331, the responsive layer 320, the underlayer 314, and the resist layer 310) may sometimes be referred to as a patterning stack 335.

In an embodiment, the resist layer 310 may be a photoresist material. The photoresist material may be a material that is compatible with any suitable type of photolithography, such as UV lithography, EUV lithography, or the like. In the case of EUV lithography, the resist layer 310 may be categorized as a chemically amplified resist (CAR) or a metal oxide resist (MOR). The resist layer 310 may be a positive resist or a negative resist. In an embodiment, the resist layer 310 may be deposited with any suitable process. In one embodiment, the resist layer 310 may be deposited with a wet process, such as a spin coating process. Other embodiments may include depositing the resist layer 310 with a dry deposition process, such as a CVD process, an ALD process, or the like.

Referring now to FIG. 3E, a cross-sectional illustration of the device 300 after a pattern 315 is formed in the resist layer 310 is shown, in accordance with an embodiment. The pattern 315 may be formed in the resist layer 310 using any suitable process. For example, the portions of the resist layer 310 may be exposed to radiation (e.g., UV radiation, EUV radiation, etc.) in order to activate a chemical reaction to alter exposed portions of the resist layer 310 (e.g., to initiate a deprotection reaction or the like). The exposed resist layer 310 may then be baked in some embodiments. A developing process may then be used to preferentially remove portions of the resist layer 310 in order to form the pattern 315 in the resist layer 310. In an embodiment, the pattern 315 may have a relatively high low frequency LWR.

Referring now to FIG. 3F, a cross-sectional illustration of the device 300 after the pattern 315 is transferred into the responsive layer 320 and the second layer 331 is shown, in accordance with an embodiment. In an embodiment, the pattern 315 may be transferred into the underlying layers using one or more etching processes, such as a dry etching process or a wet etching process. In an embodiment, the resist layer 310 and the underlayer 314 may be removed after the pattern 315 transfer process.

In an embodiment, the pattern 315 transfer process may result in the suboptimal low frequency LWR being transferred into the responsive layer 320 and the second layer 331. The sidewall 321 of the responsive layer 320 may comprise a first low frequency LWR that would otherwise result in poor pattern transfer into underlying layers. For example, the sidewall 321 may be undulating out of the plane of FIG. 3F. That is, the sidewall 321 may have an unacceptable curvature and/or roughness similar to the curvature of the sidewall 221 shown in FIG. 2A above.

Referring now to FIG. 3G, a cross-sectional illustration of the device 300 after a treatment 338 (indicated generally as a lightning bolt) is applied to the responsive layer 320 to form a treated responsive layer 322 is shown, in accordance with an embodiment. In an embodiment, the treatment 338 may result in a volumetric change in the treated responsive layer 322 that is induced by a tensile stress. The tensile stress may lead to a change in the profile of the sidewalls 323 so that the treated responsive layer 322 has a second low frequency LWR that is smaller than the first low frequency LWR of the sidewalls 321 of responsive layer 320 before treatment 338. The volumetric change in the treated responsive layer 322 may also result in the underlying second layer 331 being modified in order to reduce the low frequency LWR in the second layer 331. As such, subsequent patterning into underlying layers (e.g., the first layer 330 or the like) may have improved pattern transfer capabilities.

In an embodiment, the treatment 338 that is chosen may be dependent on the type of material that is used for the responsive layer 320. In the case of a responsive layer 320 that comprises a combination of one or more of silicon, nitrogen, hydrogen, and oxygen, the treatment 338 may comprise UV exposure. For example, a UV annealing process may be used in some embodiments. Such a UV annealing process may result in a non-equilibrium dehydrogenation of the responsive layer 320. That is, hydrogen may be removed from the lattice in order to induce a tensile stress within the responsive layer 320. In an embodiment, a temperature of the UV anneal may be chosen so that the lattice does not have sufficient energy to relax and reduce the tensile stress. For example, a temperature during the UV anneal may be approximately 450° C. or less, approximately 350° C. or less, or approximately 300° C. or less. Additionally, the frequency of the UV radiation may be tuned to allow for optimal dehydrogenation. In some embodiments, the wavelength of the UV anneal may be between approximately 150 nm and approximately 350 nm.

As can be appreciated, the non-equilibrium dehydrogenation process allows for a degree of tuning in order to provide a desired amount of tensile stress into the treated responsive layer 322. This may be accomplished by forming the responsive layer 320 with a desired concentration of hydrogen. Increases in the hydrogen concentration may result in an increase in the magnitude of the tensile stress that can be generated in the treated responsive layer 322.

In another embodiment where the responsive layer 320 comprises substantially silicon (e.g., an amorphous silicon), the treatment 338 comprises an oxidation process. In an embodiment, the oxidation process may allow for the incorporation of heteroatoms into the lattice and forms SiOₓ at a surface of the treated responsive layer 322. This may drive a volumetric expansion and tensile stress generation. In an embodiment, the oxidation process may be a thermal oxidation process that occurs at a temperature between approximately 200° C. and approximately 900° C. In other embodiments, the oxidation process may include a plasma oxidation process (e.g., a radical plasma or a direct oxygen plasma, etc.).

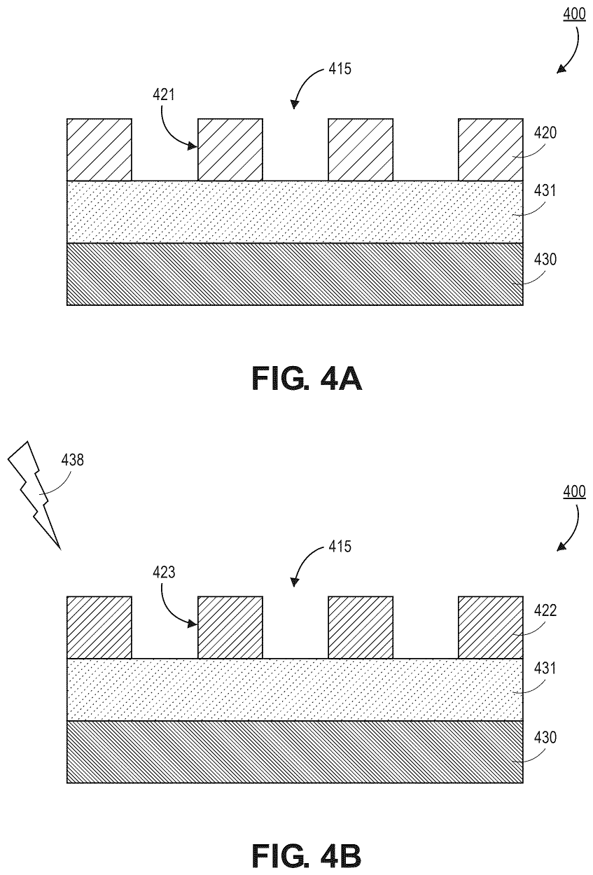

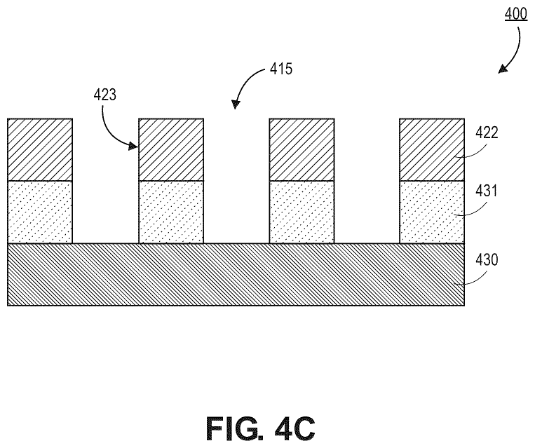

Referring now to FIGS. 4A-4C, a series of cross-sectional illustrations depicting an alternative process flow for reducing low frequency LWR in a patterning stack is shown, in accordance with an additional embodiment. In an embodiment, the processing up to the point shown in FIG. 4A may be similar to the processing described with respect to FIGS. 3A-3E.

Referring now to FIG. 4A, a cross-sectional illustration of a device 400 is shown, in accordance with an embodiment. In an embodiment, the portion of the device 400 shown in FIG. 4A illustrates a portion of the patterning stack that comprises a first layer 430, a second layer 431, and a responsive layer 420. As shown, a pattern 415 has been formed in the responsive layer 420. For example, the pattern 415 may be transferred from a patterned resist layer (not shown) similar to the resist layer 310 described in greater detail herein.

The responsive layer 420 may be similar to the responsive layer 320 described in greater detail herein. For example, the responsive layer 420 may comprise a material that is capable of being stressed (e.g., with a tensile stress) after being deposited over the second layer 431. In the state shown in FIG. 4A, the responsive layer 420 is a low stress (or substantially no stress) state. In an embodiment, the responsive layer 420 may comprise silicon (e.g., amorphous silicon), or the responsive layer 420 may comprise a combination of one or more of silicon, nitrogen, hydrogen, and hydrogen (e.g., SiN with oxygen, and a relatively high hydrogen concentration).

In an embodiment, the pattern 415 that is transferred into the responsive layer 420 may include an undesired amount of low frequency LWR. For example, the sidewalls 421 of the responsive layer 420 may have an undulating profile (when viewed from above) similar to the profile shown in FIG. 2A. In order to prevent the further transfer of a pattern 415 with poor low frequency LWR into underlying layers, a treatment may be applied to the responsive layer 420.

Referring now to FIG. 4B, a cross-sectional illustration of a portion of the device 400 after the treatment 438 is applied is shown, in accordance with an embodiment. In an embodiment, the treatment 438 may be used in order to induce a volumetric change and/or inducement of a tensile stress in the treated responsive layer 422. The treated responsive layer 422 will have sidewalls 423 that are straightened in order to reduce the low frequency LWR.

In one embodiment, the treatment 438 may comprise a UV anneal. A UV anneal may be used when the responsive layer 420 comprises a combination of one or more of silicon, nitrogen, hydrogen, and oxygen. Similar to above, a UV anneal may result in a non-equilibrium dehydrogenation that removes hydrogen from the lattice in order to induce the tensile stress within the treated responsive layer 422. The UV anneal of the responsive layer 420 may be similar to the UV anneal of the responsive layer 320 described in greater detail herein.

In another embodiment, the treatment 438 may comprise an oxidation process (e.g., a thermal oxidation, a plasma oxidation (e.g., a radical plasma or a direct oxygen plasma, etc.), or the like) of the responsive layer 420. The oxidation process may be used when the responsive layer 420 comprises silicon (e.g., amorphous silicon). The oxidation may result in the formation of a silicon oxide at the surfaces of the treated responsive layer 422, and the treated responsive layer 422 may undergo a volumetric change that induces a tensile stress in the treated responsive layer 422. In an embodiment, the oxidation of the responsive layer 420 may be similar to the oxidation of the responsive layer 320 described in greater detail herein.

Referring now to FIG. 4C, a cross-sectional illustration of the portion of the device 400 after transfer of the pattern 415 into the second layer 431 is shown, in accordance with an embodiment. In an embodiment, the second layer 431 may be patterned with the treated responsive layer 422 acting as a mask during an etching process. Since the responsive layer 422 has a reduced low frequency LWR, the resulting pattern 415 that is transferred into the second layer 431 will also exhibit good low frequency LWR. The pattern 415 may then be transferred into underlying layers (e.g., first layer 430 or the like) using additional etching processes.

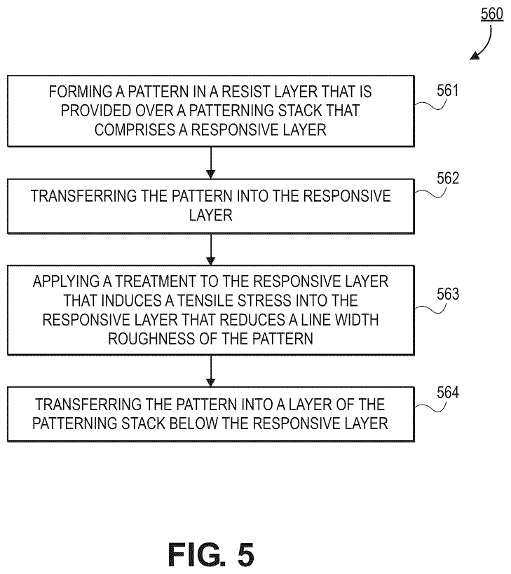

Referring now to FIG. 5, a flow diagram of a process 560 for reducing low frequency LWR in a patterning stack is shown, in accordance with an embodiment. In an embodiment, the process 560 may begin with operation 561, which comprises forming a pattern in a resist layer that is provided over a patterning stack that comprises a responsive layer. In an embodiment, the resist layer may be similar to any of the resist layers described in greater detail herein. For example, the resist layer may comprise a UV or EUV compatible photoresist material, such as a CAR or a MOR. In an embodiment, the responsive layer may be similar to any of the responsive layers described in greater detail herein. For example, the responsive layer may comprise silicon (e.g., amorphous silicon), or the responsive layer may comprise silicon and nitrogen with a relatively high hydrogen concentration.

In an embodiment, the process 560 may continue with operation 562, which comprises transferring the pattern into the responsive layer. In an embodiment, the pattern that is transferred into the responsive layer may have a relatively high low frequency LWR that substantially matches the low frequency LWR of the resist layer.

In an embodiment, the process 560 may continue with operation 563, which comprises applying a treatment to the responsive layer that induces a tensile stress in the responsive layer that reduces a LWR (e.g., a low frequency LWR) of the pattern. In an embodiment, the treatment may be similar to any of the treatments described in greater detail herein. For example, when the responsive layer comprises amorphous silicon, the treatment may be a thermal oxidation process, a plasma oxidation process (e.g., a radical plasma or a direct oxygen plasma, etc.), or the like that results in the formation of a silicon oxide layer at surfaces of the responsive layer. The incorporation of oxygen in the lattice leads to a volumetric change that induces the tensile stress in the responsive layer. In embodiments where the responsive layer comprises a combination of one or more of silicon, nitrogen, hydrogen, and oxygen, the treatment may be a UV annealing treatment. The UV annealing treatment may result in the dehydrogenation of the responsive layer that induces a tensile stress in the responsive layer. In an embodiment, the introduction of a tensile stress in the responsive layer results in a decrease in the low frequency LWR of the pattern by forcing the sidewall profile to straighten.

In an embodiment, the process 560 may continue with operation 564, which comprises transferring the pattern into a layer of the patterning stack below the responsive layer. In an embodiment, the underlying layer may comprise a carbon-based layer, an oxide-based layer, or the like. The transferred pattern will have good low frequency LWR since the pattern transfer will substantially match the profile of the treated responsive layer. The pattern may then be transferred into an underlying layer, such as a device layer that is the ultimate target of the patterning.

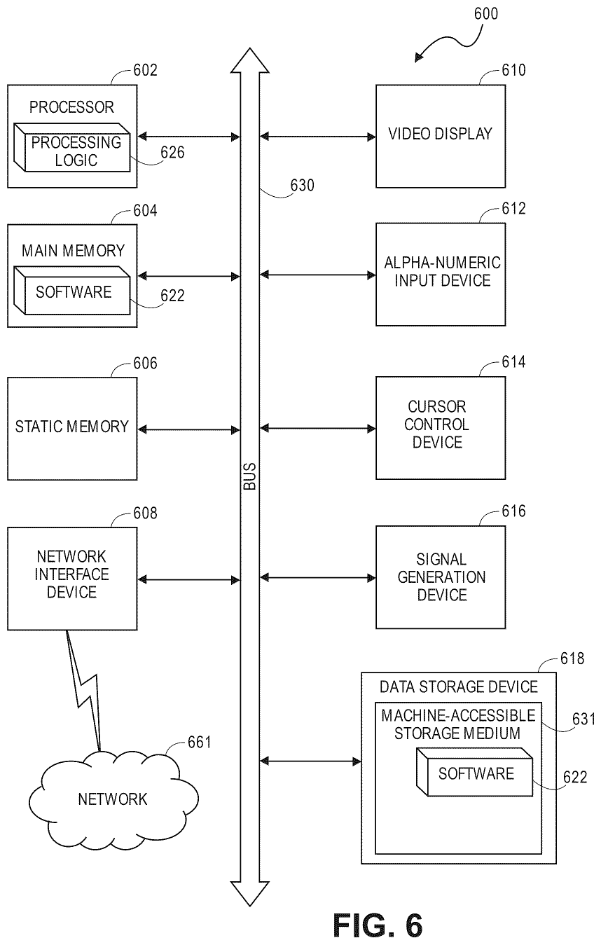

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method, comprising:
forming a pattern in a resist layer that is provided over a patterning stack that comprises a responsive layer;
transferring the pattern into the responsive layer; and
applying a treatment to the responsive layer, wherein the treatment induces a tensile stress in the responsive layer, and wherein the tensile stress reduces a line width roughness (LWR) of the pattern.

2. The method of claim 1, wherein the responsive layer comprises one or more of silicon, hydrogen, oxygen, and nitrogen.

3. The method of claim 2, wherein the treatment comprises exposing the responsive layer to ultraviolet (UV) radiation.

4. The method of claim 3, wherein a wavelength of the UV radiation is between 150 nm and 350 nm.

5. The method of claim 1, wherein the responsive layer comprises an amorphous silicon.

6. The method of claim 4, wherein the treatment comprises an oxidation of the responsive layer.

7. The method of claim 6, wherein a temperature of the oxidation is between approximately 200° C. and 900° C.

8. The method of claim 1, wherein the oxidation is a thermal oxidation, a radical plasma oxidation, or a direct oxygen plasma oxidation.

9. The method of claim 1, further comprising:
transferring the pattern in the responsive layer into a layer in the patterning stack below the responsive layer after the treatment.

10. The method of claim 1, further comprising:
transferring the pattern in the responsive layer into a layer in the patterning stack below the responsive layer before the treatment.

11. A method comprising:
forming a pattern in an extreme ultraviolet (EUV) compatible resist layer that is provided over a patterning stack that comprises a responsive layer that comprises silicon;
transferring the pattern into the responsive layer, wherein the responsive layer has a first low frequency line width roughness (LWR); and
treating the responsive layer with a treatment that induces a tensile stress in the responsive layer, wherein the tensile stress modifies the responsive layer to produce a second LWR that is lower than the first LWR.

12. The method of claim 11, wherein the responsive layer further comprises nitrogen and hydrogen, wherein an atomic percentage of hydrogen is at least 0.5%.

13. The method of claim 12, wherein the treatment is an ultraviolet (UV) radiation exposure with a temperature below approximately 300° C.

14. The method of claim 11, wherein the treatment comprises a thermal oxidation of the responsive layer.

15. The method of claim 11, wherein the resist layer is a chemically amplified resist (CAR).

16. The method of claim 11, wherein the resist layer is a metal oxide resist (MOR).

17. The method of claim 11, wherein the treatment results in a volumetric change in the responsive layer.

18. A method, comprising:
forming a pattern in a responsive layer of a patterning stack, wherein the responsive layer comprises silicon;
treating the responsive layer with an ultraviolet (UV) radiation exposure or a thermal oxidation in order to induce a tensile stress in the responsive layer; and
transferring the pattern into a layer of the patterning stack below the responsive layer.

19. The method of claim 18, wherein the responsive layer comprises an amorphous silicon.

20. The method of claim 18, wherein the responsive layer further comprises nitrogen and hydrogen.
